(19) United States
(12) Patent Application Publication
(10) Pub. No.: US 2021/0217945 A1
(43) Pub. Date: Jul. 15, 2021

(54) THERMOELECTRIC CONVERSION MODULE, AND COOLING DEVICE, TEMPERATURE MEASURING DEVICE, HEAT FLUX SENSOR, OR POWER GENERATING DEVICE INCLUDING SAME

(71) Applicant: PANASONIC INTELLECTUAL PROPERTY MANAGEMENT CO., LTD., Osaka (JP)

(72) Inventors: Daisuke SHIMIZU, Osaka (JP); Hiroki IKEUCHI, Osaka (JP)

(21) Appl. No.: 17/217,453

(22) Filed: Mar. 30, 2021

Related U.S. Application Data
(63) Continuation of application No. PCT/JP2019/034679, filed on Sep. 4, 2019.
(60) Provisional application No. 62/741,230, filed on Oct. 4, 2018.

(51) Int. Cl. H01L 35/32; H01L 35/10; H01L 35/30; F25B 21/02

(52) U.S. Cl. CPC H01L 35/32; F25B 21/02; H01L 35/30; H01L 35/10

(57) ABSTRACT

A thermoelectric conversion module includes: a thermoelectric element group including an array of first semiconductor elements and second semiconductor elements; a first substrate joined to an upper side of the thermoelectric element group; a second substrate joined to a lower side of the thermoelectric element group; and an extended portion that extends out from an end of at least one of the first substrate or the second substrate. The extended portion includes a first region and a second region, and a first width of the first region is wider than a second width of the second region, the first region being close to the first substrate or the second substrate, the second region being farther from the first substrate or the second substrate than the first region, the first width and the second width each being a width in a direction perpendicular to a longitudinal direction of the extended portion.

### CROSS REFERENCE TO RELATED APPLICATIONS

This application is a U.S. continuation application of PCT International Patent Application Number PCT/JP2019/034679 filed on Sep. 4, 2019, claiming the benefit of priority of U.S. Provisional patent Application No. 62/741,230 filed on Oct. 4, 2018, the entire contents of which are hereby incorporated by reference.

### BACKGROUND

### 1. Technical Field

The present disclosure relates to a thermoelectric conversion module; and a cooling device, a temperature measuring device, a heat flux sensor, or a power generating device including the thermoelectric conversion module. The thermoelectric conversion module absorbs and dissipates heat by using the Peltier effect and applying direct current to a series circuit including P-type thermoelectric elements and N-type thermoelectric elements.

### 2. Description of the Related Art

As energy conversion technology using thermoelectric conversion, the Peltier cooling technology and the thermoelectric generation technology, for example, Japanese Unexamined Patent Application Publication No. 2002-208741 and Japanese Unexamined Patent Application Publication No. 2007-36178, have been known conventionally. The Peltier cooling technology uses the Peltier effect to convert electrical energy into thermal energy. This technology is used to cool semiconductor devices such as CPUs used in Peltier-type refrigerators and computers, and to control the temperature of semiconductor laser oscillators for optical communications. On the other hand, the thermoelectric generation technology uses the Seebeck effect to convert thermal energy to electrical energy. This technology is expected to be used in the field of energy harvesting to collect and use exhaust heat energy.

As a thermoelectric conversion device using such thermoelectric conversion, a ceramic substrate has been known. In such a ceramic substrate, P-type thermoelectric elements and N-type thermoelectric elements are sandwiched by two substrates from up and down directions so that the P-type thermoelectric elements and the N-type thermoelectric elements alternately connect as a series circuit, and the ceramic substrate has an electrode pattern including Al₂O₃ or AlN and designed to fit the shape of thermoelectric element and the series circuit. To use this type of device, a lead wire or the like for supplying power to the thermoelectric elements is joined with a solder to a circuit board in which an electrode is formed. Therefore, person-hours for soldering connection need to be added. Instead of such a structure, module technology has been known in which a wiring portion is made using a flexible board including a resin film and having an electrode.

### SUMMARY

However, to use this type of device, the wiring connected to a power supply device is often bent to be incorporated into a housing. Therefore, sufficient joining strength for joining the substrate electrode and the lead wire has been needed. Moreover, when a flexible board is used in the wiring portion connected to the power supply device, the flexible board is required to be thin and fine as much as possible because the flexible board needs to be flexible. However, when the wiring portion is bent, a load is applied to the region of the thermoelectric element and is not sufficiently reliable as a thermoelectric conversion module.

The present disclosure aims to provide a thermoelectric conversion module capable of securing a stable power supply to a thermoelectric element and improving the reliability of the thermoelectric conversion module.

In order to achieve the above, a technical means according to a first aspect is adopted. In other words, a thermoelectric conversion module according to the first aspect includes: a thermoelectric element group that includes an array of a plurality of first semiconductor elements and a plurality of second semiconductor elements; a first substrate joined to an upper side of the thermoelectric element group; a second substrate joined to a lower side of the thermoelectric element group; and an extended portion that extends out from an end of at least one of the first substrate or the second substrate. The extended portion includes a first region and a second region, and a first width of the first region is wider than a second width of the second region, the first region being close to the first substrate or the second substrate, the second region being farther from the first substrate or the second substrate than the first region, the first width and the second width each being a width in a direction perpendicular to a longitudinal direction of the extended portion.

With this aspect, a sheet-like extended portion is provided. This makes it possible to reduce person-hours for individually connecting extended wiring in a conventional technique. Also, the structure according to this aspect has wiring patterns that are bound together, and the first constriction is formed by narrowing the pattern width to a width that is necessary for wiring. This makes the extended portion flexible. Forming the first constriction in a position farther from the thermoelectric element group makes it possible to have a bending point in a position some distance from the area where the thermoelectric elements are arrayed. This increases reliability of the thermoelectric conversion module.

In a second aspect, in addition to the structure according to the first aspect, the extended portion includes a third region having a third width that is wider than the second width, the third width being a width in the direction perpendicular to the longitudinal direction of the extended portion, the third region being farther from the first substrate or the second substrate than the second region.

With this aspect, the surface of the extended wiring in the extended portion is covered with a resist, and deterioration or damage to the extended wiring is prevented, thereby increasing reliability of the thermoelectric conversion module.

In a third aspect, in addition to the structure according to the first aspect, the extended portion includes a third region, and a connector is provided in the third region of the extended portion to be connected to an external power source.

With this aspect, the extended wiring formed in the extended portion has a power supply wiring pattern for supplying power to the thermoelectric element group from an external power source. The power supply wiring pattern is more reliable than individual lead wires that have been conventionally used. Therefore, power can be supplied stably from an external power source.

In a fourth aspect, in addition to the structure according to the first aspect, the first substrate or the second substrate from which the extended portion is extended includes: a base including an insulating material; metal wiring provided on a surface of the base on which the thermoelectric element group is disposed; and a metal layer provided on a surface of the base opposite to the surface on which the thermoelectric element group is disposed, and the metal layer is continuously provided to a region of the base where the thermoelectric element group is disposed and the first region having the first width, and a fourth width of the metal layer in the first region is wider than the second width, the fourth width being a width in the direction perpendicular to the longitudinal direction of the extended portion.

With this aspect, the metal layer on a surface opposite to the surface on which the thermoelectric element group is disposed extends in the longitudinal direction of the extended portion from the region including the thermoelectric element group, and the metal wiring and the metal layer are present on the front and back surfaces of the lower substrate and extends to the first constriction, and the metal wiring is present only on one side in a region beyond the first constriction. With this, a difference in stiffness occurs at the boundary, and serves as a bending point.

In a fifth aspect, in addition to the structure according to the first aspect, a solder including Sn, Cu, and Ni is provided between i) metal wiring and ii) the plurality of first semiconductor elements or the plurality of second semiconductor elements.

With this aspect, since the solder is a material that is soft and has an excellent flexibility, stress loading to be applied to the thermoelectric elements can be absorbed by a solder junction. Therefore, increasing reliability of the thermoelectric conversion module can be achieved.

In a sixth aspect, on a surface of the first substrate or the second substrate, an insulating layer is provided to expose a portion of a surface of metal wiring, and no insulating layer is provided on a portion around the portion of the insulating layer where the metal wiring is exposed, the surface of the first substrate or the second substrate being a surface on which the metal wiring is provided.

With this aspect, a pattern releaser for releasing the solder is formed for a resist around solder layer in a direction in which the distance between the thermoelectric elements is wider. This reduces a short circuit.

In a seventh aspect, a thermistor that detects a temperature is disposed on each of a side of the first substrate on which the thermoelectric element group is disposed and a side of the second substrate on which the thermoelectric element group is disposed.

With this aspect, a thermistor is provided on both the upper substrate and the lower substrate. The thermistor accurately measures temperatures on a heat absorbing side and a heat dissipation side, and use the temperatures to control energization of the thermoelectric conversion module.

In an eighth aspect, each of the first substrate and the second substrate includes a base including an insulating resin, and metal wiring and a metal layer are provided on respective surfaces of the base.

With this aspect, heat transfer that is transmitted sequentially from the metal layer of the upper substrate to the base, the metal wiring, and the thermoelectric element group, and to the metal wiring, the base, and the metal layer of the lower substrate can be performed uniformly in the plane.

In a ninth aspect, a cooling device includes the thermoelectric conversion module according to any one of the first to eight aspects. The extended portion is bent with respect to a surface of the second substrate, the surface including a region where the thermoelectric element group is disposed.

In a tenth aspect, a temperature measuring device includes the thermoelectric conversion module according to any one of the first to eighth aspects. The extended portion is bent with respect to a surface of the second substrate, the surface including a region where the thermoelectric element group is disposed.

In an eleventh aspect, a heat flux sensor includes: the thermoelectric conversion module according to any one of the first to eighth aspects. The extended portion is bent with respect to a surface of the second substrate, the surface including a region where the thermoelectric element group is disposed.

In a twelfth aspect, a power generating device includes the thermoelectric conversion module according to any one of the first to eighth aspects. The extended portion is bent with respect to a surface of the second substrate, the surface including a region where the thermoelectric element group is disposed.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1A is a top-view schematic diagram illustrating an overall configuration of a thermoelectric conversion module according to Embodiment 1 of the present disclosure;

FIG. 1B is a schematic cross-sectional view of the overall configuration of the thermoelectric conversion module according to Embodiment 1 of the present disclosure;

FIG. 2A is a top-view schematic diagram illustrating an overall configuration of a conventional thermoelectric conversion module;

FIG. 2B is a schematic cross-sectional view of the overall configuration of the conventional thermoelectric conversion module;

FIG. 3 is a diagram of resist releasers;

FIG. 4 is a result of a heat cycle test (comparison between a rolled copper foil and an electrolyzed copper foil);

FIG. 5 is a result of a heat cycle test (comparison of solders);

FIG. 6 is an example of implementation of housing (90 degrees bent); and

FIG. 7 is an example of implementation of housing (on the same plane).

### DETAILED DESCRIPTION OF THE EMBODIMENT

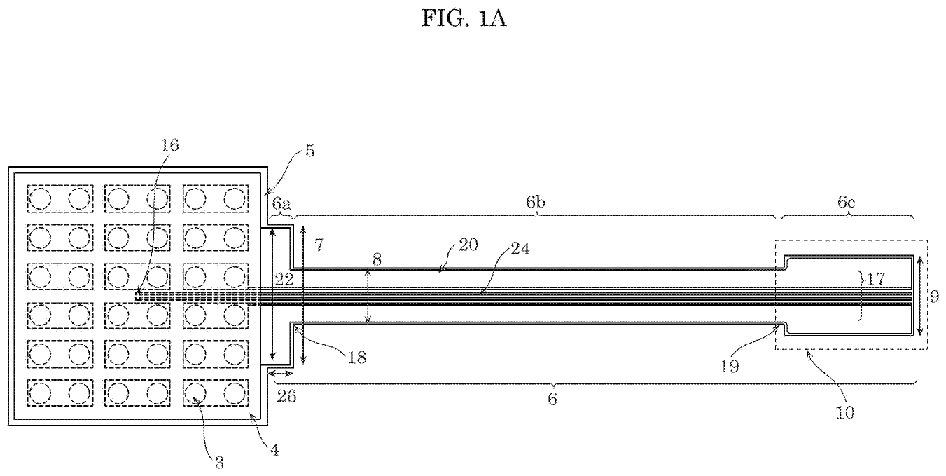

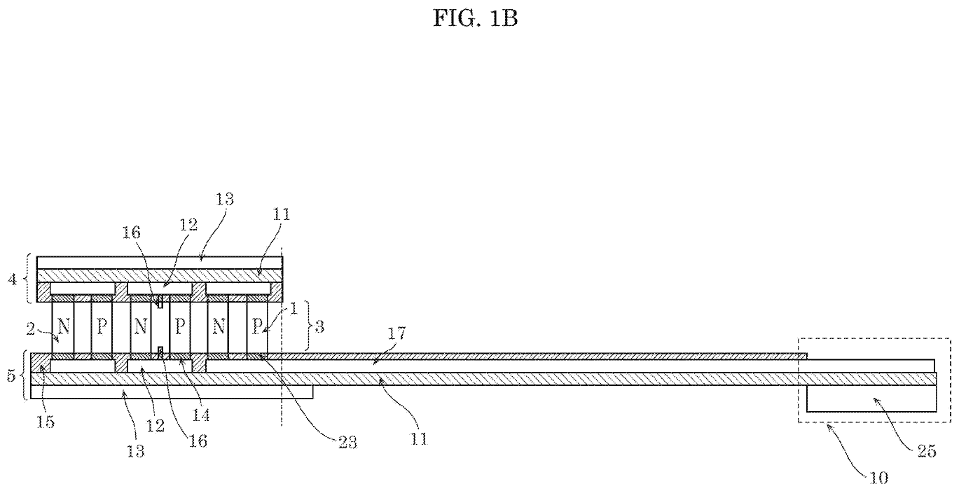

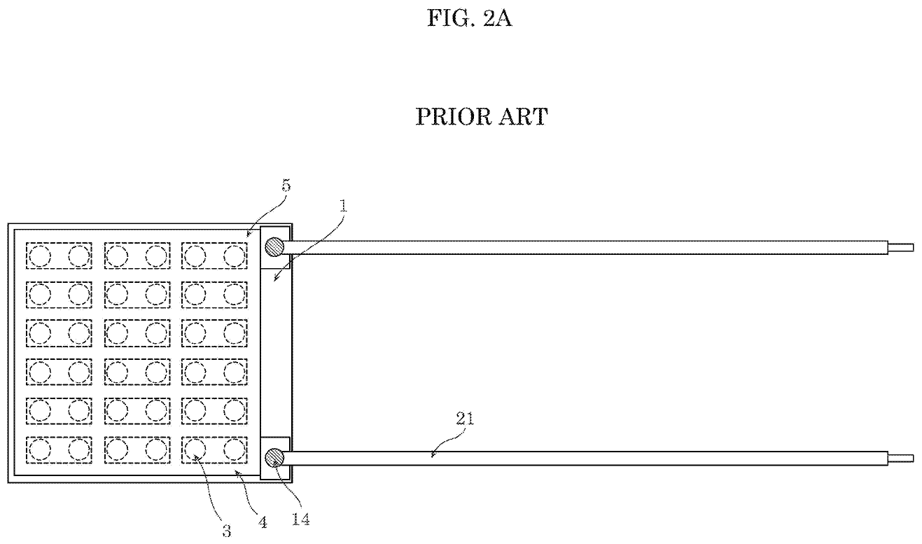

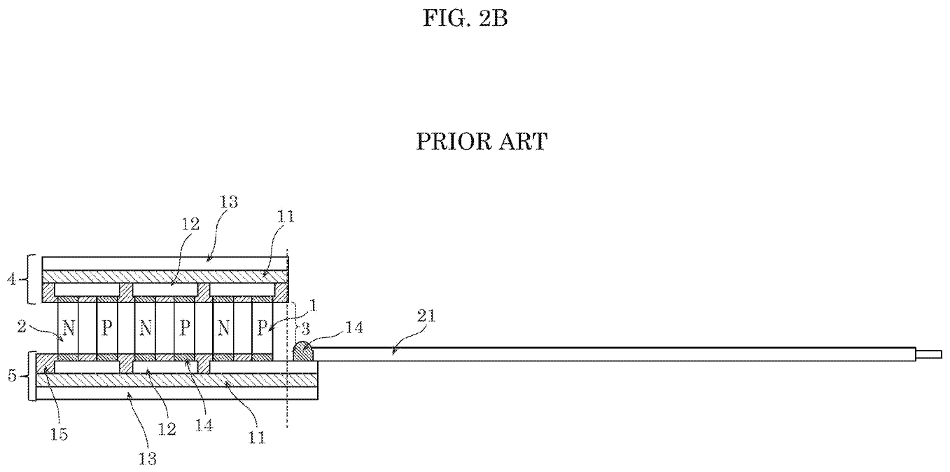

The following describes a thermoelectric conversion module according to Embodiment 1 of the present disclosure, based on FIG. 1A and FIG. 1B.

FIG. 1A and FIG. 1B each illustrate an overall configuration of the thermoelectric conversion module. FIG. 1A is a top-view schematic diagram, and FIG. 1B is a schematic cross-sectional view of the thermoelectric conversion module.

The thermoelectric conversion module according to the present embodiment mainly includes thermoelectric element group 3, upper substrate 4, and lower substrate 5. More specifically, thermoelectric element group 3 has the following structure: thermoelectric element group 3 is sandwiched between upper substrate 4 and lower substrate 5, and includes P-type thermoelectric elements 1 and N-type thermoelectric elements 2 that are alternately aligned and joined to metal wiring 12 formed on upper substrate 4 and lower substrate 5 with solder 14.

Note that the number of thermoelectric element groups 3 or the number of rows of thermoelectric element group 3 may be selected arbitrary according to a property required for the thermoelectric conversion module.

P-type thermoelectric element 1 includes a P-type semiconductor including a bismuth-tellurium (Bi—Te) based compound. Similarly, N-type thermoelectric element 2 is a semiconductor component including an N-type semiconductor including a bismuth-tellurium (Bi—Te) based compound.

Of course, other thermoelectric semiconductor elements may be used as a thermoelectric element instead of the Bi—Te based compound. For example, an iron-silicon based compound semiconductor or a cobalt-antimony based compound semiconductor may be used.

Upper and lower substrates 4 and 5 each include: base 11 having an insulating property; metal wiring 12 formed on a surface of base 11 on which thermoelectric element group 3 is disposed; metal layer 13 formed on a surface of base 11 opposite to the surface on which metal wiring 12 is provided; and resist 15 having an insulating property and overcoating the surface of base 11 on which thermoelectric element group 3 is disposed, except for the portions joined by the solder.

Regarding base 11, a resin film having flexibility and having a thermally and electrically insulating property may be selected. For example, a polyimide-based or aramid-based resin may be selected as a resin that is sufficiently strong and resistant to heat, even though it is thin. Note that the thickness of the base may be at least 5 μm and less than 50 μm, or at least 10 μm and at most 30 μm, for example. When the thickness is less than 5 μm, the base is likely to break and has a problem in strength. On the other hand, when the thickness is more than 50 μm, the thermal conductivity of the substrate decreases, and the performance of the thermoelectric conversion module decreases. In the present embodiment, a polyimide resin having a thickness of 25 μm is selected.

In metal wiring 12, electrode 23 that electrically connects thermoelectric element group 3 is formed. Electrode 23 is formed by patterning a conductive metal layer, such as copper, to an electrode pattern by an etching technique. An electrode circuit that connects the thermoelectric elements of thermoelectric element group 3 in series is formed. Furthermore, in lower substrate 5, power supply wiring pattern 20 that supplies power and sensor signal wiring pattern 24 that inputs and outputs signals between an external device and temperature sensor element 16 (e.g., thermistor) are formed in extended portion 6. Temperature sensor element 16 is a chip element and soldered to sensor signal wiring pattern 24. Temperature sensor element 16 is provided on both upper substrate 4 and lower substrate 5. Temperature sensor element 16 accurately measures temperatures on a heat absorbing side and a heat dissipation side, and use the temperatures to control energization of the thermoelectric conversion module, for example.

Electrodes 23 are included in the electrode circuit that connects thermoelectric elements in series, and are further connected to power supply wiring pattern 20 that supplies power. One of electrodes 23 is connected to a positive terminal of a direct-current power supply, and the remaining one of electrodes 23 is connected to a negative terminal of the direct-current power supply.

Power supply wiring pattern 20 is formed in extended portion 6, and adjacent to power supply wiring pattern 20 on the same plane, sensor signal wiring pattern 24 is formed. Extended portion 6 includes first extended region 6a, second extended region 6b, and connector portion 6c. First extended region 6a is formed to provide a bending point at a position away from thermoelectric element group 3 to improve reliability of the thermoelectric conversion module. In first extended region 6a, metal layer 13 on a surface opposite to the surface on which thermoelectric element group 3 is disposed extends along a longitudinal direction of extended portion 6. In other words, metal wiring 12 and metal layer 13 that are on the front and back surfaces of lower substrate 5 extend to first constriction 18, and in second region 6b, which is beyond first constriction 18, metal wiring 12 is present on only one surface of the substrate. A difference in stiffness occurs at the boundary between first constriction 18 and second region 6b, and the boundary functions as a bending point.

Therefore, the bending point of extended portion 6 is at a position away from lower substrate 5 by the length of the extended region (protruded portion) 6 from the region on lower substrate 5 where the thermoelectric elements are provided. Thus, the stress resulting from bending has little effect on the junction between the thermoelectric elements and lower substrate 5, and malfunction such as breakage of the junction can be suppressed.

Note that width 7 of the first extended region may be greater than or equal to width 8 of the second extended region, i.e., greater than or equal to the width of the first constriction, and may have a width less than the width of the array area of thermoelectric element group 3, i.e., less than the width of the thermoelectric conversion module. When width 7 of the first extended region is less than the width of second extended region 6b, the effect of the bending point decreases and the reliability decreases. When width 7 of the first extended region is greater than or equal to the width of the thermoelectric conversion module, the width is greater than the standard size of the thermoelectric conversion module. Protruded width 26 in the longitudinal direction of first extended region 6a may be at least half the size (the diameter or the length of a side) of the thermoelectric element, and less than width 7 of the first extended region. When protruded width 26 is less than half the size (the diameter or the length of a side) of the thermoelectric element, the bending load is concentrated on a thermoelectric element near the bending point and the electrodes of the substrates. This reduces the reliability of the thermoelectric conversion module. When protruded width 26 is greater than or equal to width 7 of the first extended region, the proportion of first extended region 6a in the extended portion increases in the longitudinal direction. Thus, the flexibility of extended portion 6b decreases. In the present embodiment, width 7 of the first extended portion is 8 mm, and protruded width 26 in the longitudinal direction is 1 mm.

Second extended region 6b is narrowed to a width of wiring of power supply wiring pattern 20 that suites a usage current standard, which is one of use conditions of the thermoelectric conversion module, and metal layer 13 is not formed on the surface opposite to the surface on which thermoelectric element group 3 is disposed. This structure reduces stiffness and ensures flexibility. Note that width 8 of the second extended region may be at least 1 mm and at most width 7 of the first extended region. When width 8 of the second extended region is less than 1 mm, only a small current can be applied, for example, an allowable value of the current to be applied to the thermoelectric conversion module is a current equal to or less than 0.5 A. When width 8 of the second extended region is greater than or equal to width 7 of the first extended region, the flexibility of the wiring portion decreases. In the present embodiment, since the maximum current to be applied is 3 A, the width of power supply wiring pattern 20 is designed to be 2 mm and width 8 of the second extended region including sensor signal pattern 24 is 5.5 mm to ensure flexibility.

Furthermore, the tip portion of the extended portion in the longitudinal direction is designed to have a width determined by considering matching of power supply pattern 20 and sensor signal wiring pattern 24 with connector 10, and to ensure stiffness by reinforcing plate 25 for the force to be applied when the tip portion is inserted to connector 10.

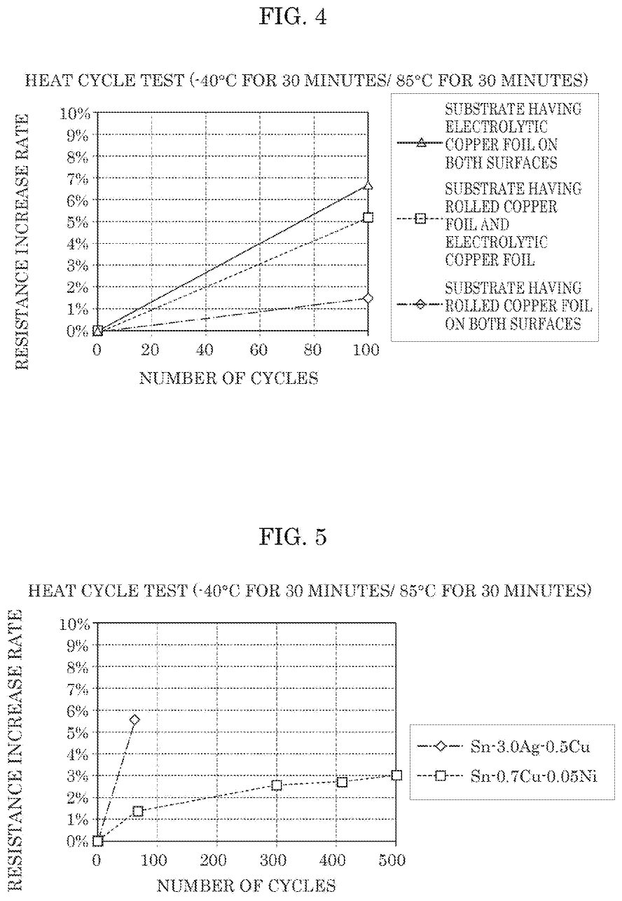

The conductive metallic material of metal wiring 12 and metal layer 13 is copper in the present embodiment. A rolled copper foil material of isotropic crystalline is selected in the present embodiment, and it is not an electrolytic copper foil of a columnar crystal. Use of a rolled copper foil achieves high reliability than an electrolytic copper foil. This is because thermoelectric elements have been conventionally formed with a Bi—Te based material having cleavage, and such thermoelectric elements have not been reliable due to thermal stress applied via a solder junction. Such thermal stress results from expansion and contraction of upper substrate 4 and lower substrate 5 due to thermal history. A rolled copper foil is a soft and highly flexible material and reduces the stress loading to be applied from upper and lower substrates 4 and 5 to thermoelectric element group 3. In the present embodiment, a comparative experiment for comparing heat cycle tests between rolled and electrolytic copper foils was conducted, and the effects were confirmed (see FIG. 4). Resistance increase rates after the thermoelectric conversion modules were subjected to 100 cycles were compared. The resistance increase rate of the substrate having a rolled copper foil on both surfaces was 1.5%, whereas the resistance increase rate of the substrate having an electrolytic copper foil on both surfaces was 6.7%. The result shows that the substrate having an electrolytic copper foil deteriorated, and the substrate having rolled copper foil is advantageous.

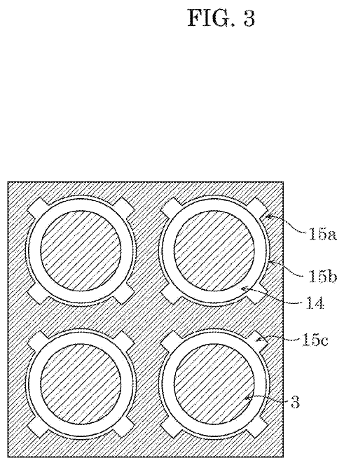

As solder 14, Sn.0.7Cu.0.05Ni—Ge is used in the present embodiment. Use of an Sn—Cu—Ni-based solder achieves high reliability of the thermoelectric conversion module. This is because thermoelectric elements have been conventionally formed with a Bi—Te based material having cleavage, and such thermoelectric elements have not been reliable due to thermal stress applied via a solder junction. Such thermal stress results from expansion and contraction of upper substrate 4 and lower substrate 5 due to thermal history. An Sn—Cu—Ni based solder is a soft and highly flexible material compared to an Sn—Ag—Cu based solder that is commonly used, and absorbs stress loading applied from upper and lower substrates 4 and 5 to thermoelectric element group 3. In the present embodiment, a comparative experiment for comparing heat cycle tests between solders have been conducted, and the effects were confirmed (see FIG. 5). The resistance increase rate of the thermoelectric conversion module including the Sn.3Ag.0.5Cu solder was 5.5% at the 61th cycle, whereas the resistance increase rate of the thermoelectric conversion module including the Sn—Cu—Ni based solder was 3.0% at the 500th cycle and the resistance increase was suppressed. The result shows that the Sn—Cu—Ni based solder is advantageous. Upper substrate 4 and lower substrate 5 are overcoated with solder resist (insulating layer) 15 to prevent a short circuit due to a solder bridge between thermoelectric elements arranged adjacent to each other, as well as misalignment of the thermoelectric elements that may occur in melting the solder. In this example, to prevent a short circuit due to a solder bridge, which has been a problem when the thermoelectric elements of thermoelectric element group 3 are arranged at a small pitch, pattern releasers 15c are formed for resist around solder layer 15a in a direction in which the distance between the thermoelectric elements is wider, as illustrated in FIG. 3. This can reduce a short circuit. In the present embodiment, the interval between the thermoelectric elements is 85 um and the thermoelectric elements are arranged in a grid, pattern releasers 15c having a size of 10% of the area of resist evacuator 15b in a diagonal direction in which the interval between the elements widens (interval between the elements: 534 μm) are provided. As a result, short circuits occurred in two thermoelectric conversion modules out of eight thermoelectric conversion modules during assembling, but when the pattern releasers were formed, the occurrence of short circuits was reduced to zero. Note that in this example, for convenience, upper substrate 4 with respect to thermoelectric element group 3 is the heat absorbing side, and lower substrate 5 with respect to thermoelectric element group 3 is the heat dissipation side. However, the relationship between the heat dissipation and the heat absorption can be interchanged when the polarity of the direct-current power supply to be applied to the series circuit of thermoelectric elements is reversed. Therefore, the setting relationship is not limited to the relationship illustrated in FIG. 1A and FIG. 1B.

Next, a cooling device and a temperature measuring device, for example, that include the thermoelectric conversion module according to the present embodiment will be described.

The thermoelectric conversion module according to the present embodiment is provided to various kinds of cooling devices, temperature measuring devices, and heat flux sensors, and used for various purposes, such as cooling electronic components and human bodies and measuring a temperature or a heat flux. Moreover, the thermoelectric conversion module according to the present embodiment may be provided to a temperature regulating device that lowers or raises a temperature from a reference temperature such as an ambient temperature to control the temperature precisely, as well as a power generating device that converts heat into electricity.

The thermoelectric conversion device according to the present embodiment may be provided to a cooling device, a temperature measuring device, or a heat flux sensor, for example, in a state that the extended portion cannot be bent, or in a state that the extended portion is bent.

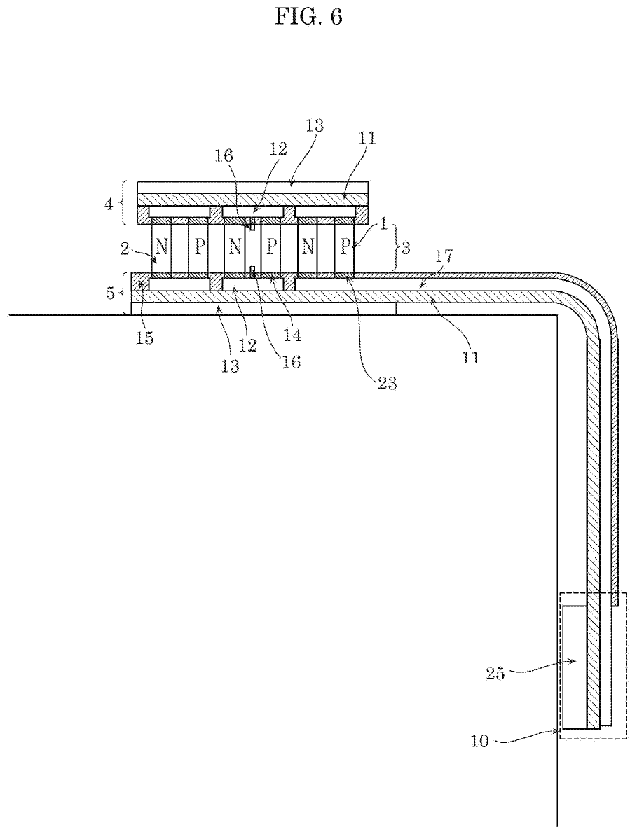

Since the extended portion of the lower substrate of the thermoelectric conversion module according to the present embodiment is flexible, the lower substrate can be bent toward the upper substrate or a side opposite to the upper substrate as illustrated in FIG. 6. When the lower substrate is bent toward the side of the upper substrate, the bending angle is an angle that the lower substrate does not interfere with the upper substrate. Since at least the lower substrate and its extended portion are flexible, when a sensing unit or a temperature measuring unit of a heat flux sensor that measures a heat flux or a temperature measuring device that measures the temperature has a hollow elongated cylindrical shape, the lower substrate may be bent to 80 to 100 degrees, or for example, approximately 90 degrees. With this, the thermoelectric conversion module can be housed in the temperature measuring unit such that the extended portion in the longitudinal direction of the sensing unit or the temperature measuring unit is housed along the longitudinal direction of the lower substrate.

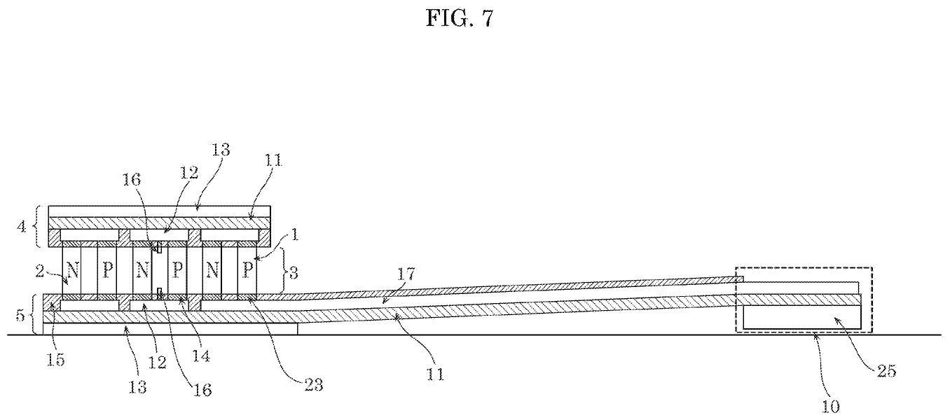

Furthermore, as illustrated in FIG. 7, the bending angle of the extended portion may be less than 90 degrees. As illustrated in FIG. 7, the lower surface of the metal layer on the lower surface of the lower substrate and the lower surface of the connector is placed on the same surface, the distance between the lower surface of the connector and the base is greater than the thickness of the metal layer on the lower surface of the lower substrate. Therefore, the extended portion of the lower substrate is bent toward the upper substrate with respect to the surface on which the thermoelectric element group of the lower substrate is provided.

Note that the heat flux sensor is a transducer that generates an electrical signal proportional to a total heat rate applied to the surface of the sensor.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

What is claimed is:

1. A thermoelectric conversion module, comprising:
a thermoelectric element group that includes an array of a plurality of first semiconductor elements and a plurality of second semiconductor elements;
a first substrate joined to an upper side of the thermoelectric element group;
a second substrate joined to a lower side of the thermoelectric element group; and
an extended portion that extends out from an end of at least one of the first substrate or the second substrate, wherein
the extended portion includes a first region and a second region, and a first width of the first region is wider than a second width of the second region, the first region being close to the first substrate or the second substrate, the second region being farther from the first substrate or the second substrate than the first region, the first width and the second width each being a width in a direction perpendicular to a longitudinal direction of the extended portion.

2. The thermoelectric conversion module according to claim 1, wherein
the extended portion includes a third region having a third width that is wider than the second width, the third width being a width in the direction perpendicular to the longitudinal direction of the extended portion, the third region being farther from the first substrate or the second substrate than the second region.

3. The thermoelectric conversion module according to claim 1, wherein
the extended portion includes a third region having a third width, and a connector is provided in the third region of the extended portion for connection to an external power source, the third region being farther from the first substrate or the second substrate than the second region.

4. The thermoelectric conversion module according to claim 1, wherein
the first substrate or the second substrate from which the extended portion is extended includes:
a base including an insulating material;
metal wiring provided on a surface of the base on which the thermoelectric element group is disposed; and
a metal layer provided on a surface of the base opposite to the surface on which the thermoelectric element group is disposed, and
the metal layer is continuously provided to a region of the base where the thermoelectric element group is disposed and the first region having the first width, and a fourth width of the metal layer in the first region is wider than the second width, the fourth width being a width in the direction perpendicular to the longitudinal direction of the extended portion.

5. The thermoelectric conversion module according to claim 1, wherein
a solder including Sn, Cu, and Ni is provided between i) metal wiring provided on a surface of a base and ii) the plurality of first semiconductor elements or the plurality of second semiconductor elements, the surface of the base being a surface on which the thermoelectric element group is disposed, the base including an insulating material and being included in the first substrate or the second substrate.

6. The thermoelectric conversion module according to claim 1, wherein
on a surface of the first substrate or the second substrate, an insulating layer is provided to expose a portion of a surface of metal wiring, and no insulating layer is provided on a portion around the portion of the insulating layer where the metal wiring is exposed, the surface of the first substrate or the second substrate being on a side of a surface of a base on which the thermoelectric element group is disposed, the metal wiring being provided on the surface of the base on which the thermoelectric element group is disposed, the base including an insulating material and being included in the first substrate or the second substrate.

7. The thermoelectric conversion module according to claim 1, wherein
a thermistor that detects a temperature is disposed on each of a side of the first substrate on which the thermoelectric element group is disposed and a side of the second substrate on which the thermoelectric element group is disposed.

8. The thermoelectric conversion module according to claim 1, wherein
each of the first substrate and the second substrate includes a base including an insulating resin, and metal wiring and a metal layer are provided on respective surfaces of the base.

9. A cooling device, comprising:
the thermoelectric conversion module according to claim 1, wherein
the extended portion is bent with respect to a surface of the second substrate, the surface including a region where the thermoelectric element group is disposed.

10. A temperature measuring device, comprising:
the thermoelectric conversion module according to claim 1, wherein
the extended portion is bent with respect to a surface of the second substrate, the surface including a region where the thermoelectric element group is disposed.

11. A heat flux sensor, comprising:
the thermoelectric conversion module according to claim 1, wherein
the extended portion is bent with respect to a surface of the second substrate, the surface including a region where the thermoelectric element group is disposed.

12. A power generating device, comprising:
the thermoelectric conversion module according to claim 1, wherein
the extended portion is bent with respect to a surface of the second substrate, the surface including a region where the thermoelectric element group is disposed.
